(19) United States
(12) Patent Application Publication
(10) Pub. No.: US 2007/0187840 A1
(43) Pub. Date: Aug. 16, 2007

(54) Nanoscale probes for electrophysiological applications

(76) Inventors: Ludovico M. Dell'Acqua-Bellavitis, Cohoes, NY (US); Jake D. Ballard, Troy, NY (US); Rena Bizios, San Antonio, TX (US); Richard W. Siegel, Menands, NY (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 11/603,348

(22) Filed: Nov. 21, 2006

Related U.S. Application Data
(60) Provisional application No. 60/738,469, filed on Nov. 21, 2005.

(51) Int. Cl. H01L 23/52

(52) U.S. Cl. 257/784

(57) ABSTRACT

A device comprising a planar integrated circuit that includes an array of electrodes and at least one nanostructure, having a major axis, in electrical contact with at least one electrode. The device forms an interface between an integrated circuit platform and electro-physiologically active cells and is used in manipulate the same.

### RELATED APPLICATIONS

This application claims the benefit of U.S. Provisional Application No. 60/738,469, filed on Nov. 21, 2005. The entire teachings of the above application are incorporated herein by reference.

### GOVERNMENT SUPPORT

The invention was supported, in whole or in part, by a grant DMR-0117792 from the US National Science Foundation. The Government has certain rights in the invention.

### BACKGROUND OF THE INVENTION

Existing devices used for in vitro electrophysiological experiments lack sufficient resolution in space, are highly invasive and suffer from ineffective electrical coupling between the cells and the electrical circuit that is used for stimulation and/or recording measurements.

### SUMMARY OF THE INVENTION

There is a need for devices with (i) enhanced signal selectivity, featuring nanometer resolution in space and millisecond resolution in time, (ii) improved cell-biomaterial interaction, mitigating invasiveness and extending device and interface lifetime, and (iii) increased signal discrimination, maximizing signal/noise ratio of the device—to be used for in vitro electrophysiological experiments on electrically-active biological cells and with the capability to be used for neural electrophysiological imaging and stimulation. A new set of multielectrode probes, which utilize integrated circuit fabrication techniques to manufacture an integrated circuit platform (IC platform) which is subsequently contacted with conductor/insulator composite constructs featuring segregated conducting paths (interface) to overcome the high invasiveness associated with conventional microelectrodes, have been designed, fabricated and tested.

In one embodiment, the present invention is a device, comprising a planar integrated circuit that includes an array of electrodes, and at least one nanostructure in electrical contact with at least one electrode. The nanostructures have a major axis.

In another embodiment, the present invention is a method of manufacturing an electrical device, comprising growing two or more nanostructures in situ, said nanostructures having a major axis, and electrically connecting the nanostructures with a planar integrated circuit that includes an array of electrodes, thereby forming an array of nanostructures.

In another embodiment, the present invention is a method of recording or sending electrical signal to/from a cell, comprising contacting a cell with a device of the present invention.

In another embodiment, the present invention is a method of diagnosing a disorder, comprising contacting a cell in a pathological state caused by said disorder with a device that includes a planar integrated circuit that includes an array of electrodes; and at least one nanostructure having a major axis in electrical contact with at least one electrode. Preferably, the disorder is cancer or a neurodegenerative disorder.

The devices and methods of the present invention possess a number of advantages over the previously reported devices. Specifically, the devices of the present invention have a three-dimensional electrode array positioned on otherwise planar circuitry; the electrodes in direct contact with the cell(s) consist of high aspect ratio nanostructures (nanotubes, nanowires or a combination thereof) contacted to the underlying IC platform; the use of conducting high aspect ratio nanostructured electrode arrays permit their chemical functionalization; spatial resolution (number of conducting channels per unit area) of the devices is increased as a direct effect of the reduction to nanoscale dimensions of individual, electrically-insulated high-aspect ratio conducting nanostructures; cell-biomaterial interaction is improved as a direct effect of a reduction of the minimum feature sizes of the electrodes in contact with the cells, which leads to a reduction in encapsulation by scar tissue and immune response by the biological target tissue; and signal discrimination is increased as a direct effect of the increase in surface area brought by specific treatments of the electrode surface topography, therefore maximizing signal/noise ratio of the device.

### BRIEF DESCRIPTION OF THE DRAWINGS

FIG. 1 is a diagram illustrating the interface developed between three different types of IC platforms with varying minimum feature sizes and bio-electrically active cells.

FIG. 2 shows a sequence of the steps used in the fabrication of all IC device platforms.

FIG. 3 shows the principle of assembly of one embodiment of the device of the present invention comprising an array of nanotubes infiltrated with PMMA in electrical contact with an integrated circuit.

FIG. 4 shows the principle of assembly an alternative embodiment of the device of the present invention comprising insulating templates metallized to obtain an array of electrically-conducting metallic nanowires embedded within an insulating template.

FIG. 5 shows the sequence of processes undertaken to fabricate one embodiment of the interface—a gold-plated copper anodized alumina composite.

FIG. 6 shows a representative recording array for one embodiment of IC platform at four different magnifications.

FIG. 7 is an optical micrograph of one embodiment of the IC platform featuring a minimum feature size of 200 nm, which was manufactured using e-beam lithography.

### DETAILED DESCRIPTION OF THE INVENTION

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

The device of the invention possesses (i) nanometric resolution in space and millisecond resolution in time, (ii) improved cell-biomaterial interaction, (iii) increased signal discrimination and is intended for neural electrophysiological imaging (electrical recording and stimulation) applications.

In one embodiment, the present invention is a device that comprises (i) an IC platform and (ii) a composite interface. Arrays of equi-spaced multiple metal (e.g. gold) electrodes are fabricated using combined e-beam and optical lithography to achieve three types of IC platforms with three different scales of resolution. In one embodiment of composite interface, carbon nanotubes are synthesized on silicon dioxide substrates using a chemical vapor deposition method. Subsequently, the carbon nanotube arrays are infiltrated with in situ polymerized polymethylmethacrylate to achieve electrical insulation between adjacent nanotube bundles. The carbon nanotube arrays grown on silicon dioxide exhibit uniform length and a high level of alignment, which is preserved subsequent to the in situ polymerization process.

In an alternative embodiment of the composite interface, porous insulator templates are infiltrated with a conductor via metallization. The resulting metallic nanorods grown within the template yield segregated conducting paths that are of uniform density and do not exhibit interruptions or gaps along their length. Moreover, the nanorods exhibit a high level of alignment, which is preserved throughout the manufacturing process.

The fabricated composite constructs exhibit electrical conductivity and connectivity between two faces of the composite along the length of the nanotubes or nanorods. The devices can be deployed as an interface between ICs and electrically-active biological cells.

Accordingly, in one embodiment, the present invention is a device, comprising a planar integrated circuit that includes an array of electrodes and at least one nanostructure in electrical contact with at least one electrode. The term “nanostructure”, as used herein, includes carbon nanotubes and/or bundles thereof, metal nanorods or nanowires (used interchangeably herein) and, generally, any electrically conducting nanotube or nanowire, made from materials including metals, semiconductors (e.g., Si, Ge or ZnO), or a conducting polymer. As used herein, the terms “nanotube” means a structure that is essentially hollow, while the term “nanowire” refers to a structure that is essentially solid. Preferably, each nanostructure has a major axis along one dimension of the nanostructure that is greater than the other dimensions by a substantial ratio, e.g. greater than 10-fold, preferably greater than 100-fold, more preferably, greater than 100-fold. An array of nanostructures, each having major axis, is said to form a “high aspect ratio nanostructures.” Such high aspect ratio nanostructures, employed by the present invention, can include a carbon nanotube, metal nanowire or metal nanorod, or a bundle of any of these structures. Preferably, a major axis of a nanostructure is non-coplanar with the plane of the integrated circuit. More preferably, at least one nanostructure is essentially perpendicular to the plane of the integrated circuit.

In a preferred embodiment, the device of the present invention further includes electrical insulation disposed between two or more nanotubes or nanowires or nanorods. Preferably, the electrical insulation is in form of an in situ formed polymer, for example, in situ formed polymethylmethacrylate (PMMA) or in form of rational insulating templates, formed by a material such as alumina.

In one embodiment, the nanostructures are chemically functionalized. Any of the functionalization methods known in the art can be used. (See A. García, I. Bustero, R. Mu{tilde under (n)}oz, L. Goikotxea, I. Obieta, Carbon nanotubes for biological devices. Physica status solidi a, 2006. 203: p. 1117-1123; A. Yan, B. W. Lau, B. S. Weissman, I. Külaots, N. Y. C. Yang, A. B. Kane, R. H. Hurt, Biocompatible, hydrophilic, supramolecular carbon nanoparticles for cell delivery. Advanced materials, 2006. 18: p. 2373-2378; B. K. Price, J. M. Tour, Functionalization of single-walled carbon nanotubes “on water”. Journal of the American Chemical Society, 2006. 128: p. 12899-12904; B. L. Fletcher, T. E. McKnight, A. V. Melechko, M. L. Simpson, M. J. Doktycz, Biochemical functionalization of vertically aligned carbon nanofibres. Nanotechnology, 2006. 17: p. 2032-2039 H. Park, J. Zhao, J. P. Lu, Effects of sidewall functionalization on conducting properties of single wall carbon nanotubes. Nano letters, 2006. 6: p. 916-919; J. Li, H. Grennberg, Microwave-assisted covalent sidewall functionalization of multiwalled carbon nanotubes. Chemistry—a European journal, 2006. 12: p. 3869-3875; J. S. Ye, F. S. Sheu, Functionalization of CNTs: New routes towards the development of novel electrochemical sensors. Current Nanoscience, 2006. 2: p. 319-327; Lukaszewicz, J. P., Carbon materials for chemical sensors: A review. Sensor letters, 2006. 4: p. 53-98; T. Zhang, M. B. Nix, B.-Y. Yoo, M. A. Deshusses, N. V. Myung, Electrochemically functionalized single-walled carbon nanotube gas sensor. Electroanalysis, 2006. 18: p. 1153-1158; V. N. Khabashesku, M. X. Pulikkathara, Chemical modification of carbon nanotubes. Mendeleev Communications, 2006. 2: p. 61-66; X. Chen, U. C. Tam, J. L. Czlapinski, G. S. Lee, D. Rabuka, A. Zettl, C. R. Bertozzi, Interfacing carbon nanotubes with living cells. Journal of the American Chemical Society, 2006. 128: p. 6292-6293).

The nanostructures can be functionalized with inorganic salts or ions such as calcium, chloride, inorganic phosphorous, potassium, selenium, sodium; proteins such as poly-L-lysine, laminin, bilirubin, albumin, insuline, hemoglobin, collagen, fibronectin, fibrinogen; enzymes such as alkaline phosphatase, lactate dehydrogenase, glutamate oxalacetate transaminase; carbohydrates such as glucose; lipids such as triglycerides nucleic acids such as DNA, RNA, m-RNA, t-RNA or selected portions thereof, vitamins such as beta-carotene, bioflavonoids, biotin, choline, CoQ-10, essential fatty acids, folic acid, hesperidin, inositol, para-aminobenzoic acid, rutin, vitamin A, vitamin B complex, vitamin B-1 thiamine, vitamin B-2 riboflavin, vitamin B-3 niacin/niacinamide, vitamin B-5 pantothenic acid, vitamin B-6 pyridoxine, vitamin B-9 folic acid, vitamin B-12 cyanocobalamine, vitamin B-15 dimethylglycine, vitamin B-17 leatrile or amygdalin, vitamin C, vitamin D, vitamin E, vitamin F unsaturated fats, vitamin G, vitamin J, vitamin K, vitamin P; antibodies such as immunoglobulin A, immunoglobulin D, immunoglobulin E, immunoglobulin G, immunoglobulin M; steroids and hormones such as cholesterol, cortisol, follicle stimulating hormone, growth hormone, leutinizing hormone, platelet-derived growth factor, fibroblast growth factor, parathyroid hormone, progesterone, prolactin, prostaglandins, testosterone, thyroid stimulating hormone; aminoacids such as alanine, arginine, asparagine, aspartic acid, cysteine, glutamine, glutamic acid, glycine, histidine, isoleucine, leucine, lysine, methionine, phenylalanine, proline, serine, threonine, tryptophan, valine, and aminoacid derivatives such as creatine.

Preferably, functionalization of the nanotubes or nanorods is attained by conformal deposition of chemical moieties (e.g., proteins) on the upper surface of the interface. Preferred moieties include proteins poly-L-lysine and laminin.

In a preferred embodiment, chemical functionalization is achieved by treating the surface of the nanostructures with a solution of poly-L-lysine and laminin in water for a duration of 2 hours. Preferably, such treatment is performed just prior to deploying a device of the invention, e.g. prior to contacting an electro-physiologically active cell.

Three geometrically different types of IC platforms for electrophysiological studies of neuronal cells at the multi-cellular, inter-cellular and intra-cellular levels are summarized in Table 1:

TABLE 1

| | Device Type | | |
|---|---|---|---|
| | Multi-cellular | Inter-cellular | Intra-cellular |
| Similitude ratio | 1.00 X | 10.00 X | 37.50 X |
| Symmetry | Center-symmetric | Center-symmetric | Center-symmetric |
| Lead width | 7.50 μm | 750.00 nm | 200.00 nm |
| at the center | width and pitch | width and pitch | width and pitch |
| Lead width | 7.50 μm width | 5.00 μm width | 5.00 μm width |
| at the pads (periphery) | 92.50 μm pitch | 95.00 μm pitch | 95.00 μm pitch |
| Well size at the center | w = (5.00-7.50) μm | w = (500.00-750.00) nm | w = (50.00-200.00) nm |
| (width * height) | h = (5.00-7.50) μm | h = (500.00-750.00) nm | h = (50.00-200.00) nm |
| Min. conducting feature size | 7.50 μm | 750.00 nm | 200.00 nm |
| Distance between | 62.00 μm | 6.20 μm | 1.65 μm |
| channel tips at center | | | |
| Total recording area at center | w = 2.00 mm | w = 200.00 μm | w = 53.33 μm |
| (width * height) | h = 400.00 μm | h = 40.00 μm | h = 10.66 μm |
| Recording area | $832.44 \frac{{μm}^{2}}{channel}$ | $8.32 \frac{{μm}^{2}}{channel}$ | $0.59 \frac{{μm}^{2}}{channel}$ |
| Device space resolution (channel density) | $1.20 * {10}^{- 3} \frac{{μm}^{2}}{channel}$ | $0.12 \frac{channels}{{μm}^{2}}$ | $1.68 \frac{channels}{{μm}^{2}}$ |
| Total device size | width = 10.27 mm | width = 10.27 mm | width = 10.27 mm |
| | height = 10.27 mm | height = 10.27 mm | height = 10.27 mm |
| External pads size | width = 100 μm | width = 100 μm | width = 100 μm |
| | height = 100 μm | height = 100 μm | height = 100 μm |
| Well size at the peripheral | w = 100 μm | w = 100 μm | w = 100 μm |
| pads (width * height) | h = 100 μm | h = 100 μm | h = 100 μm |
| Distance between | 100 μm | 100 μm | 100 μm |
| external pads on a row | | | |
| Distance between pad rows | 600 μm | 600 μm | 600 μm |

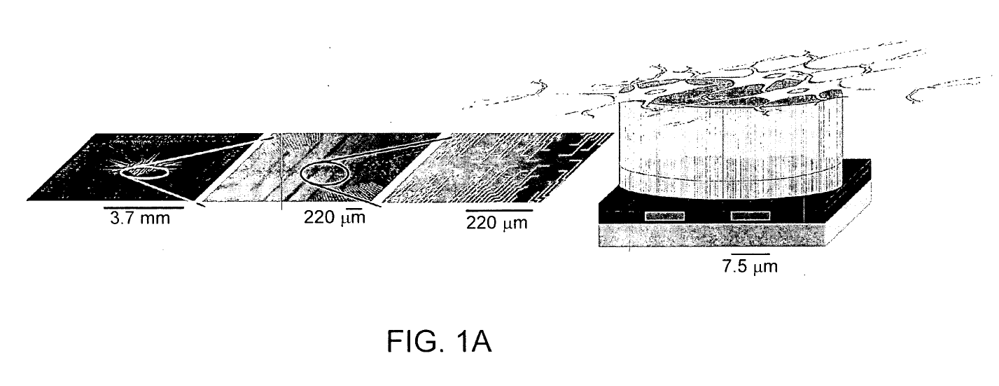

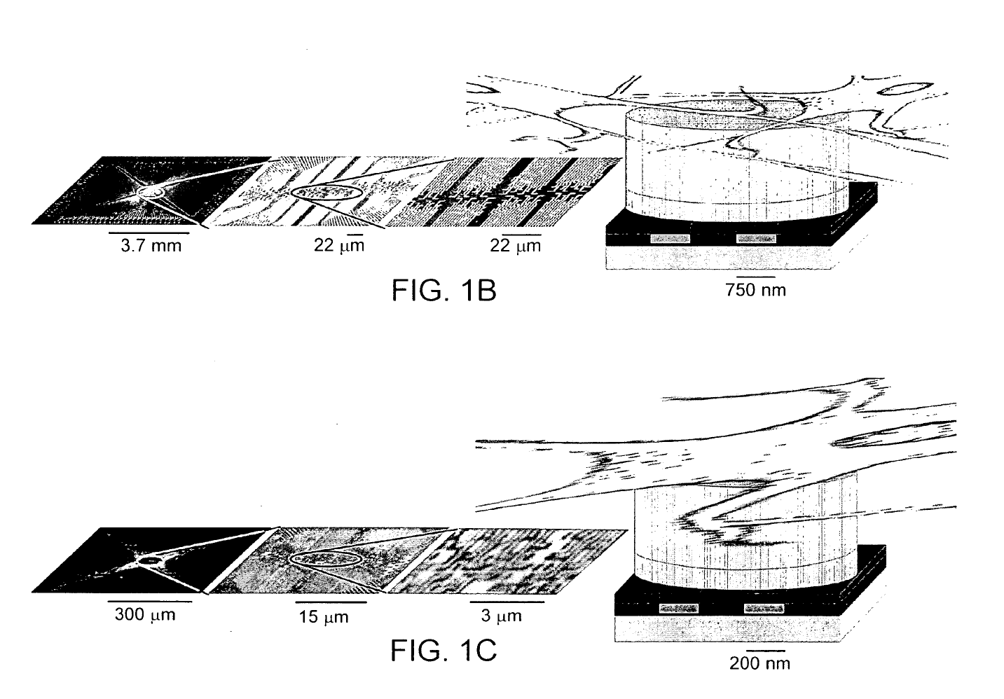

The diagram in FIG. 1 illustrates the three types of devices of the present invention subsequent to interfacing with bio-electrically active cells via a composite construct.

Each device features 224 individual channels and has identical geometric arrays of patterned electrical connections at the external periphery; each IC platform is a square (each side 10.27 mm). The central recording area for each integrated circuit consists of an array of equi-spaced electrode tips with the capability to map neural signals at increasingly finer spatial resolution. The device platform with the coarsest spatial resolution (multi-cellular) is intended to overcome many of the problems associated with conventional microelectrodes and to stimulate and record extracellular biopotentials. (See G. W. Gross, J. H. Lucas, Long-term monitoring of spontaneous single unit activity from neuronal monolayer networks cultured on photoetched multielectrode surfaces. Journal of electrophysiological techniques, 1982. 9: p. 55-67; and K. D. Wise, J. B. Angell, A. Starr, An integrated-circuit approach to extracellular microelectrodes. IEEE transactions on bio-medical engineering, 1970. 17: p. 238-247.) The circuit with the intermediate spatial resolution (inter-cellular) has a smaller and more densely packed recording array designed to monitor the interaction between one cell and selected neighboring cells. The device platform with the finest spatial resolution (intra-cellular) is intended for probing the functions of individual cells.

The IC platforms for multi- and inter-cellular electrophysiological stimulation and recording are fabricated using optical lithography techniques. Electron-beam (e-beam) lithography is used on the central part of the intra-cellular devices. Deployment of e-beam lithography is utilized to achieve minimum feature sizes in the range of 50-200 nm; this requirement generally cannot be met by optical lithography alone. Because of the sequential scanning of the surface by an electron beam in a raster pattern over nanometric surface portions, deployment of e-beam lithography has the drawback of a considerable prolongation of the exposure time needed for each intra-cellular IC. This problem of manufacturing intra-cellular devices is solved by combining e-beam lithography (for the central portions of the IC, with nanometric minimum feature sizes) and optical lithography (for the peripheral portions of the IC, with micrometric minimum feature sizes).

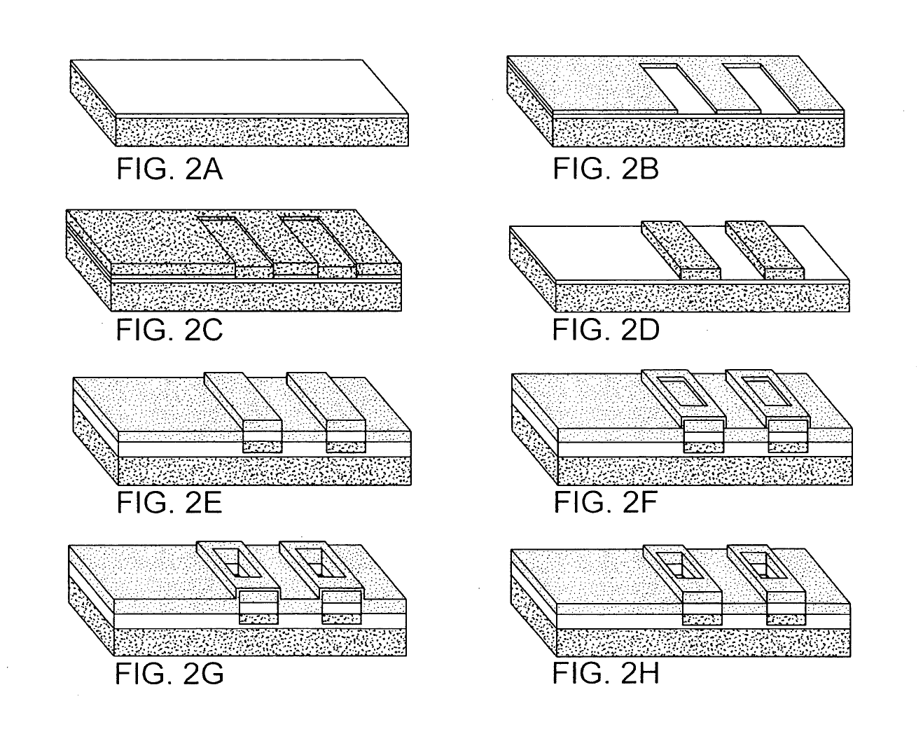

The fabrication steps used for the three types of device platforms of interest to the present study are schematically represented in FIG. 2. In step A, silicon wafers are thermally oxidized. In step B, a first lithographic step is performed using positive photoresists. In step C, a titanium and gold bi-layer is subsequently deposited on select portions of the silicon dioxide, ensuring discontinuous film deposition along the vertical walls and uniform coverage on the horizontal surfaces. In step D, the metallic bi-layer in all regions of the platform previously covered by resist is chemically lifted off. In step E, CVD oxide and CVD nitride were then grown on the platform to provide electrical insulation of adjacent channels. In step F, a second lithographic step exposes selected portions of the electrode tips. In step G, the electrode tips are exposed using CVD nitride and oxide etch. In step H, the photoresist is stripped from the device. The above-described procedure was performed using the facilities at the Cornell Nano-Scale Science & Technology Facility (a member of the National Nanofabrication Users Network), which is supported by the National Science Foundation under Grant ECS-9731293, its users, Cornell University, and Industrial Affiliates.

In one embodiment, the device disclosed in the present invention comprises arrays of aligned, multi-wall, electrically-conducting carbon nanotubes grown by chemical vapor deposition (CVD) and subsequently infiltrated with in-situ-polymerized polymethylmethacrylate (PMMA) to achieve electrical insulation between adjacent nanotube bundles.

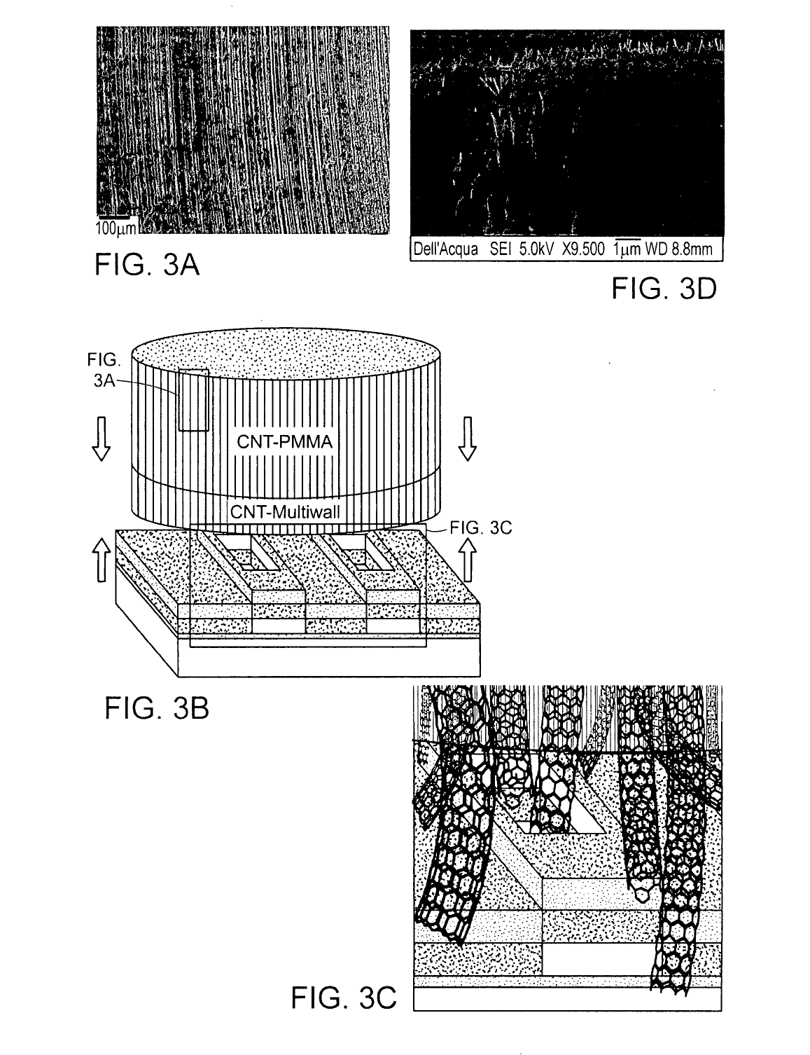

Multi-wall carbon nanotubes (CNTs) are grown on silicon dioxide substrates using an established CVD method. (See L. M. Dell'Acqua-Bellavitis, J. D. Ballard, P. M. Ajayan, R. W. Siegel, Kinetics for the synthesis reaction of aligned carbon nanotubes: a study based on in situ diffractography. Nano Letters, 2004. 4: p. 1613-1620.) The resulting aligned carbon nanotube arrays are infiltrated with methylmethacrylate (MMA) monomer, which is subsequently polymerized in situ to form polymethylmethacrylate (PMMA) to achieve electrical insulation between adjacent CNT bundles. (See Raravikar, N. R., Novel approaches towards developing composite architectures based on carbon nanotubes and polymers. Ph.D. Thesis—Materials Science and Engineering. 2004, Troy N.Y.-USA: Rensselaer Polytechnic Institute.) Such composites are positioned in intimate contact with a multiple electrode array IC platform, as presented in FIG. 3. Panel A illustrates a representative scanning electron micrograph of vertically aligned carbon nanotube arrays on a silicon dioxide substrate. Panel B is a schematic representation of the positioning of the vertically aligned carbon nanotube array on the IC. The lower surface of the nanotube/PMMA composite is chemically etched in order to expose the tips of carbon nanotube bundles. Panel C shows exposed nanotube tips, which enable electrical contact between underlying gold electrodes and bundles of vertically aligned carbon nanotubes. Panel D is a representative scanning electron micrograph of vertically aligned carbon nanotubes protruding from the PMMA matrix. Both faces of the interface show the same configuration of protruding nanotubes. (Schematic representations of panels B and C are not to scale.)

In this phase, the lower surface of the nanotube/PMMA composite is chemically and mechanically etched in order to expose the tips of the carbon nanotube bundles, therefore enabling electrical contact between underlying gold electrodes on the IC template and vertically aligned carbon nanotubes on the interface. The synthesized multi-wall nanotubes are characterized by transmission electron microscopy and were found to have an average diameter of 40 nm. The average distance between adjacent nanotubes is characterized by field emission scanning electron microscopy and generally varies in a range from 80 nm to 200 nm. The nanotubes are characterized to be good electrical conductors and the composite construct features connectivity from one side adjacent to the IC platform to the opposite side adjacent to the cells.

In a second embodiment, the devices disclosed in the present invention comprise rationally insulating templates (for example, rationally-anodized alumina templates) with pores which are then fully metallized to obtain an array of vertically-aligned, electrically-conducting metallic nanorods embedded within an insulating matrix.

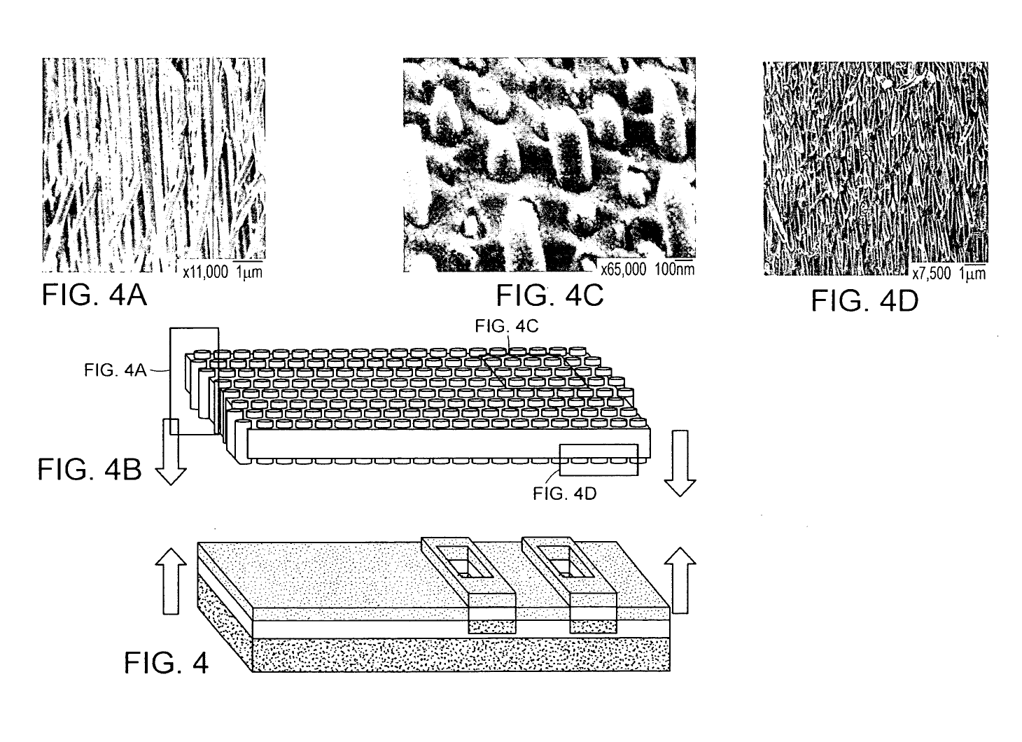

High purity metallic foils are oxidized to create a porous medium featuring vertically-segregated uninterrupted pores, according to established techniques (See G. E. Possin, A method for forming very small diameter wires. Review of scientific instruments, 1970. 41: p. 772-774; G. E. Thompson, R. C. Furneaux, G. C. Wood, J. A. Richardson, J. S. Goode, Nucleation and growth of porous anodic films on aluminium. Nature, 1978. 272: p. 433-435; H. Masuda, H. Yamada, M. Satoh, H. Asoh, Highly ordered nanochannel-array architecture in anodic alumina. Applied physics letters, 1997. 71: p. 2770-2772). The pore diameter in the resulting anodized templates can be varied by changing the anodization potential or the solution in the electrochemical cell. Such porous templates are then metallized using physical vapor deposition (i.e., electron beam deposition) on one side only, to create a seed layer which is then used as a nucleating support for further metallization to occur via electrochemical methods (See for example J. Dini, Electrodeposition of Copper, in M. Schlesinger, M. Paunovic, Modern electroplating, 4th edition, John Wiley & Sons, 2000). Since the pore diameter can be varied as a function of the anodization potential or of the solution used, it follows that the nanowire diameter can also change to directly match the pore size of the template. The seed layer is then electropolished and the insulating matrix is then partially etched to expose tips of metallic nanowires. The metallic nanowires are subsequently coated electrolessly with inert metals such as gold, in order to eliminate the occurrence of toxic byproducts liberated by the device tips in the highly corrosive cellular medium. Such composites are then positioned in intimate contact with a multiple electrode array IC platform, as presented in FIG. 4. Panel A illustrates a representative scanning electron micrograph of the lateral view of vertically aligned metallic nanowire arrays embedded within an alumina porous insulator. Panel B is a schematic representation of the positioning of the vertically aligned metallic nanowire array on the IC. The initial seeding layer is electropolished from the lower surface of the composite interface, in order to expose the tips of the metallic nanowire array. Panel C shows the exposed metallic nanowire tips, which enable electrical contact between underlying gold electrodes on the IC platform and individual nanowires in the interface. Panel D is a representative scanning electron micrograph of vertically aligned metallic nanowires protruding from the insulating matrix. Both faces of the interface show the same configuration of protruding metallic nanowires. (Schematic representations of panels B are not to scale.)

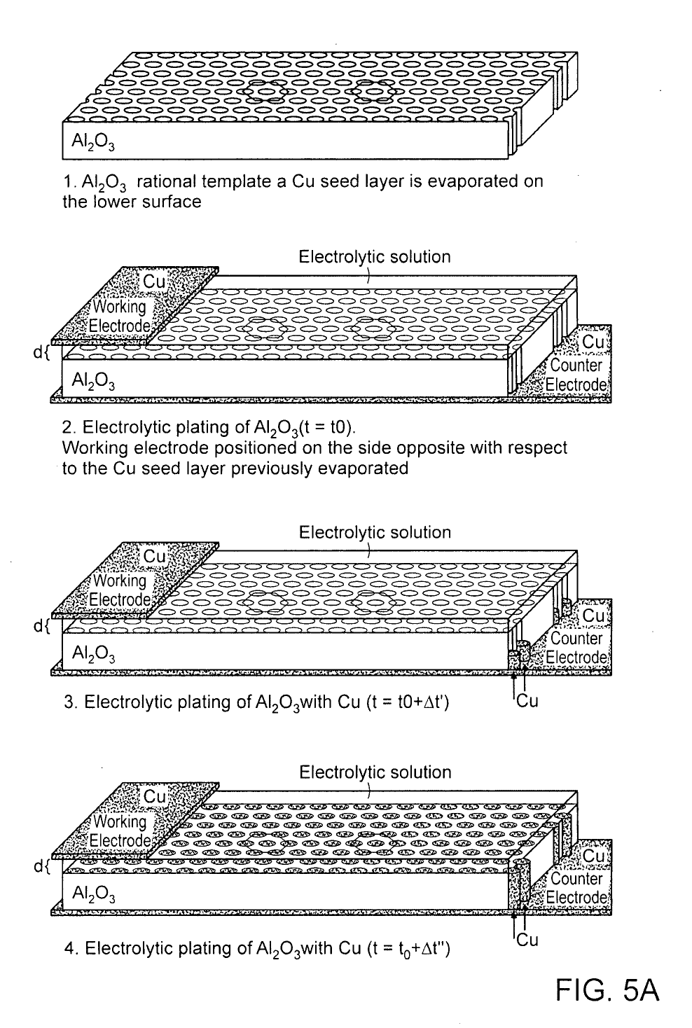

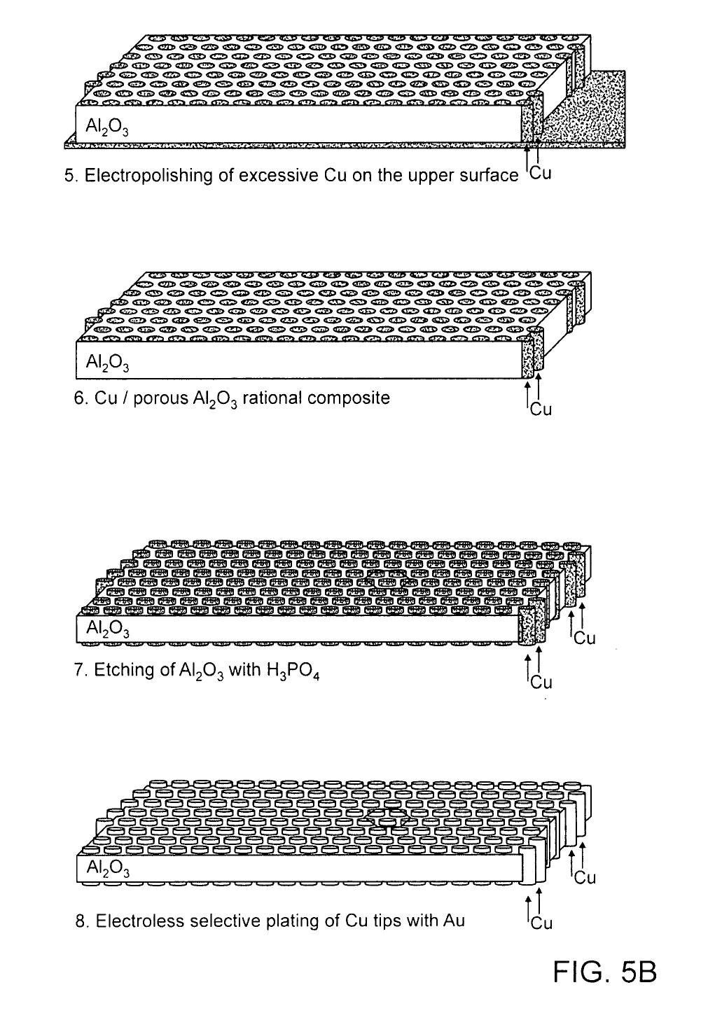

FIG. 5 represents the sequence of processes undertaken to fabricate the gold-plated copper/anodized alumina composite. Panel 1 illustrates that the Al₂O₃ template was e-beam evaporated with a layer of copper on its lower (non visible) side. Panel 2-4 show that the seed layer of copper on the lower side of the alumina template was used as the counter electrode in an appropriate electrolytic cell. The working electrode was constituted by a high surface area copper bulk solid. The copper grew within the pores of the alumina template in a time-dependent fashion. Panel 5 illustrates an electropolishing process which was then needed in order to remove the seed Cu layer and the excessive copper deposited during electropolishing. This step was needed in order to prevent cross-talk between adjacent conducting copper rods on the upper surface, which would decrease the lateral resolution of the device. Panel 6 shows that the copper was made coplanar with respect to the alumina, and therefore had to be etched in H₃PO₄ (panel 7), in order to change the profiles of the Cu rods from planar to three-dimensional. Panel 8 illustrates that finally, the protruding Cu nanorods were selectively plated with a gold film using an electroless process. The alumina was not plated with gold in this process.

The metallic nanowires are characterized to be excellent electrical conductors and the composite construct features connectivity from one side adjacent to the IC platform to the opposite side adjacent to the cells. Additionally, the cross-talk between adjacent conducting nanorods in the insulating matrix is eliminated in light of the vertical segregation of the pores in the interface.

The devices and the methods of the present invention achieved at least two distinct goals: (i) IC platforms with arrays of equi-spaced gold electrodes are designed and fabricated. These are deposited on insulating silicon dioxide substrates by means of lift-off lithography, followed by subsequent chemical vapor deposition (CVD) oxidation and CVD nitridation. An additional lithography step, followed by plasma etching on selected portions of the respective substrates, is then used to expose the tips of the electrodes to designated electric signal recording loci. (ii) Nanotube/PMMA composite structures, which can be used in conjunction with the arrays of equi-spaced electrodes and have the capability of interfacing integrated circuits to biological cells, are synthesized. The electrical resistance of these composites was measured at room temperature ex situ—separately from the IC—in a dry non-aqueous environment and was characterized to be equal to 1.8 kΩ (kilo-ohms). In particular, the measurement of the electrical resistance is performed by contacting one side of the composite with a copper plate and the opposite side of the composite with a 4 μm wide gold microtip. Since the relative dimensions of the recording tip used in the electrical measurement exceed the diameter of individual nanotubes by two orders of magnitude, the electrical resistance measured corresponds to an aggregate measurement on bundles of adjacent carbon nanotubes and does not correspond to the resistance of individual multi-wall nanotubes. (iii) Composites based on metallic nanowires or nanorods and rationally-anodized templates are synthesized; these can be used in conjunction with the arrays of equi-spaced electrodes and have the capability of interfacing integrated circuits to biological cells. When copper was used in the plating step to manufacture these composites, the electrical resistance of the structures was measured at room temperature ex situ—separately from the IC—in a dry non-aqueous environment and was characterized to be equal to 30 Ω. In particular, the measurement of the electrical resistance is performed by contacting one side of the composite with a copper plate and the opposite side of the composite with a 4 μm wide gold microtip. Since the relative dimensions of the recording tip used in the electrical measurement exceed the diameter of individual nanowires by two orders of magnitude, the electrical resistance measured corresponds to an aggregate measurement on bundles of adjacent metallic nanowires and does not correspond to the resistance of individual multi-wall nanotubes.

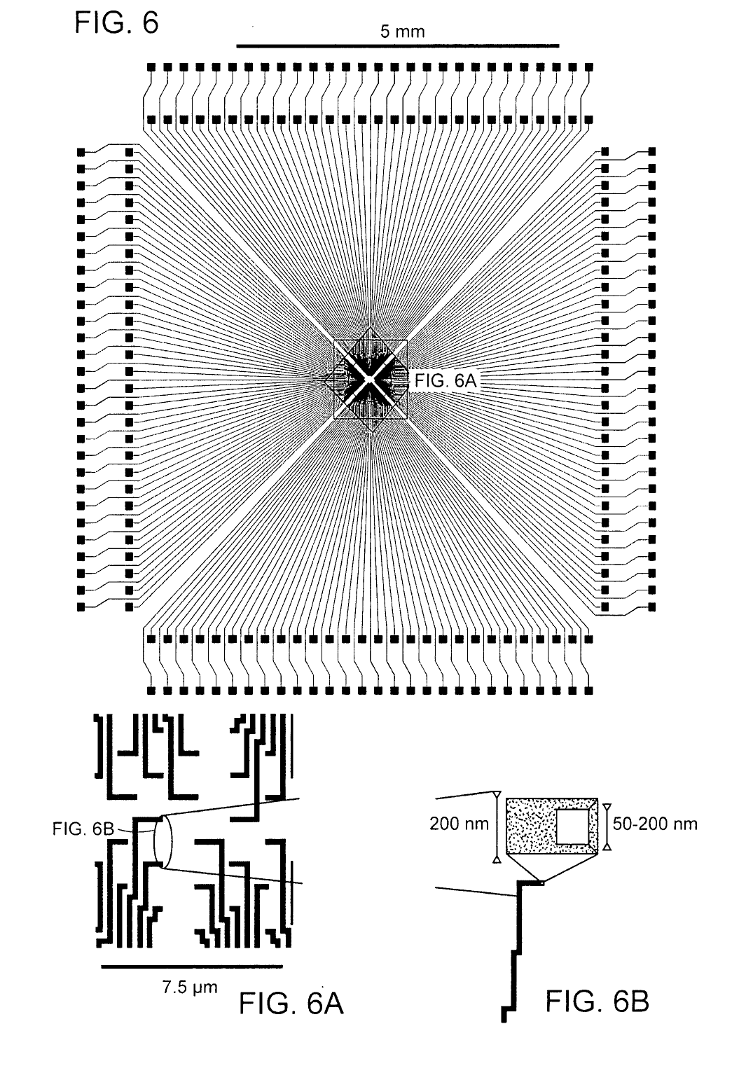

A representative example of the platform for the novel intra-cellular device is shown in FIG. 6. FIG. 6 illustrates a schematic of the geometry of this integrated circuit for electrophysiological experiments shown at four different magnifications. Highlights of the geometry of the section made by e-beam lithography as well as the geometry and dimensions of the electrode tips are also shown. The left panel shows a sections of the device built using optical and e-beam lithography. The middle panel shows a detail of the device section fabricated using e-beam lithography. The right panel shows individual electrode tip for the intra-cellular device at two magnification levels.

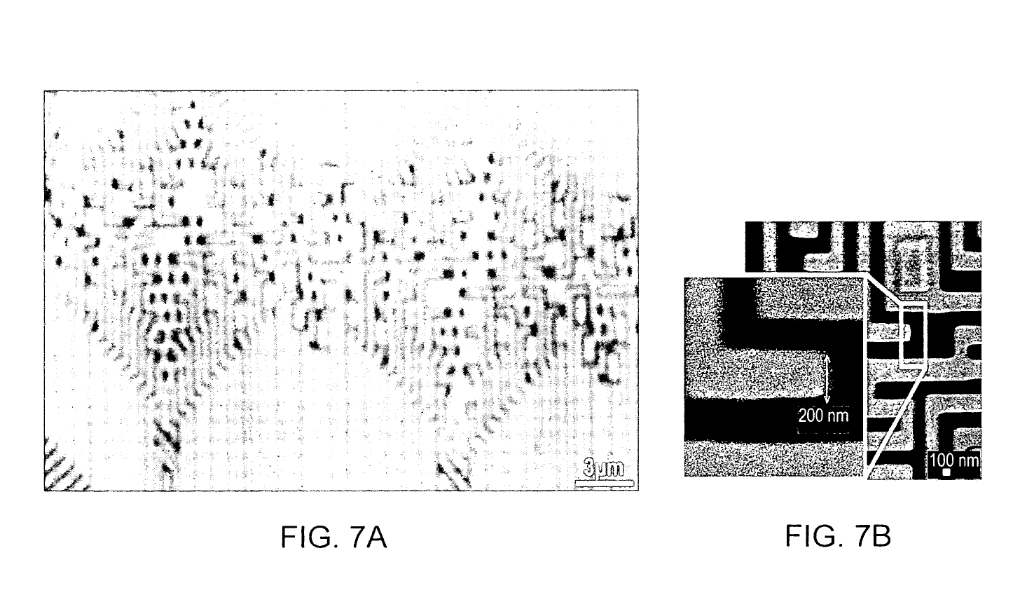

The three types of IC can be qualitatively characterized by optical microscopy and by scanning electron microscopy throughout the width of the central recording area in the array before the CVD oxidation and nitridation processes described in FIG. 2. Spatial resolution of the device and the individual features typically are preserved with a high level of accuracy and reproducibility (see FIG. 7).

With reference to FIG. 7, the left panel is a field emission scanning electron micrograph illustrating select channels of the intra-cellular device at different magnifications. The right panel of FIG. 7 is a micrograph of an electrode tip.

In one further embodiment of assembly of the device to external circuitry, the IC platform is surface-mounted onto an IC holder which in turn is assembled onto a printed circuit board. The printed circuit board for the three different types of devices is then assembled to external circuitry leading to appropriate data acquisition hardware. The cells are delivered to the central portion of the recording array, where the composite interface is positioned in intimate contact to the IC platform, using appropriate fluidics and cuvette apparatus in order to inhibit shorting of the external electrical connections. The complete device can be used in conjunction with a reflection confocal or fluorescence microscope.

In one embodiment, the devices of the present invention are employed in a method of recording or sending electrical signal to/from a biological cell. The method comprises contacting a biological cell with a device of the invention. The biological cells can be any physiologically active cells. Preferably, the biological cell is a myocardial cell, a neuronal cell, an osteoblast, a fibroblast, a skeletal muscle cell, a photoreceptor cell, or a cochlear hair cells. Alternatively, the biological cell is a progenitor stem cell selected from an embryonic stem cell, an adult stem cells, and an umbilical cord stem cells.

In another embodiment, the present invention is a method of diagnosing a disorder, comprising contacting a cell in a pathological state caused by said disorder with a device of the invention. Preferably, the disorder is cancer or a neurodegenerative disorder. Alternatively, the disorder can be any disorder listed herein.

The biological cell that are employed with the present invention can be in a pathological state caused by infectious and parasitic diseases such as intestinal infectious diseases, tuberculosis, certain zoonotic bacterial diseases, other bacterial diseases, infections with a predominantly sexual mode of transmission, other spirochaetal diseases, other diseases caused by chlamydiae, rickettsioses, viral infections of the central nervous system, arthropod-borne viral fevers and viral haemorrhagic fevers, viral infections characterized by skin and mucous membrane lesions, viral hepatitis or human immunodeficiency virus [HIV] disease, other viral diseases, mycoses, protozoal diseases, helminthiases, pediculosis, acariasis and other infestations, sequelae of infectious and parasitic diseases, bacterial, viral and other infectious agents; the pathological state can be caused by neoplasms (cancers) such as malignant neoplasm of the lip, oral cavity and pharynx, of the digestive organs, of the respiratory and intrathoracic organs, of the bone and articular cartilage, of the skin, of the mesothelial and soft tissue, of the breast, of the female genital organs, of the male genital organs, of the urinary tract, of the eye, brain and other parts of central nervous system, of the thyroid and other endocrine glands, or such as malignant neoplasms of ill-defined, secondary and unspecified sites, or such as malignant neoplasms, stated or presumed to be primary, of lymphoid, haematopoietic and related tissue, or such as malignant neoplasms of independent (primary) multiple sites, or such as in situ neoplasms, benign neoplasms, or neoplasms of uncertain or unknown behaviour; the pathological state can be caused by mental and behavioural disorders such as organic, including symptomatic, mental disorders, mental and behavioural disorders due to psychoactive substance use, schizophrenia, schizotypal and delusional disorders, mood [affective] disorders, neurotic, stress-related and somatoform disorders, or behavioural syndromes associated with physiological disturbances and physical factors or disorders of adult personality and behaviour or mental retardation or disorders of psychological development or behavioural and emotional disorders with onset usually occurring in childhood and adolescence; the pathological state can be caused by inflammatory diseases of the central nervous system, systemic atrophies primarily affecting the central nervous system, extrapyramidal and movement disorders, other degenerative diseases of the nervous system, demyelinating diseases of the central nervous system, episodic and paroxysmal disorders, nerve, nerve root and plexus disorders, polyneuropathies and other disorders of the peripheral nervous system, diseases of myoneural junction and muscle, cerebral palsy and other paralytic syndromes; the pathological state can be caused by diseases of the eye such as disorders of eyelid, lacrimal system and orbit, disorders of conjunctiva, disorders of sclera, cornea, iris and ciliary body, disorders of lens, disorders of choroid and retina, glaucoma, disorders of vitreous body and globe, disorders of optic nerve and visual pathways, disorders of ocular muscles, binocular movement, accommodation and refraction, visual disturbances and blindness; the pathological state caused by disorders of the inner ear; the pathological state can be caused by diseases of the circulatory system such as acute rheumatic fever, chronic rheumatic heart diseases, hypertensive diseases, ischaemic heart diseases, pulmonary heart disease and diseases of pulmonary circulation, other forms of heart disease, cerebrovascular diseases, diseases of arteries, arterioles and capillaries, diseases of veins, lymphatic vessels and lymph nodes, not elsewhere classified; the pathological state can be caused by congenital malformations, deformations and chromosomal abnormalities such as congenital malformations of the nervous system, congenital malformations of eye, ear, face and neck, congenital malformations of the circulatory system, congenital malformations of the respiratory system; the pathological state can be caused by endocrine, nutritional and metabolic diseases such as disorders of thyroid gland, diabetes mellitus, other disorders of glucose regulation and pancreatic internal secretion, disorders of other endocrine glands, malnutrition, other nutritional deficiencies, obesity and other hyperalimentation or metabolic disorders.

### EXEMPLIFICATION

Design and Fabrication of Nanotube/PMMA Composite Interfaces Between Bio-Electrically Active Cells and ICs

Synthesis of Vertically Aligned Nanotube Substrates by Chemical Vapor Deposition. Vertically aligned carbon nanotubes arrays were synthesized by catalytic pyrolysis of a carbon source following a suitable modification of published techniques. (See L. M. Dell'Acqua-Bellavitis, J. D. Ballard, P. M. Ajayan, R. W. Siegel, Kinetics for the synthesis reaction of aligned carbon nanotubes: a study based on in situ diffractography. Nano letters, 2004. 4: p. 1613-1620; and Dell'Acqua-Bellavitis, L. M., Kinetics for the synthesis reaction of aligned carbon nanotubes. A study based on in situ diffractography, in Materials science and engineering. 2004, Rensselaer Polytechnic Institute: Troy N.Y.)

Ferrocene—C₁₀H₁₀Fe—was used as the catalyst precursor, while xylenes—C₆H₄(CH₃)₂—were used as the carbon source.

Infiltration of Vertically Aligned Carbon Nanotube Substrates with Polymethylmethacrylate. Emphasis is here given to the polymerization of PMMA in light of the need to achieve electrical insulation between adjacent CNT bundles and in light of the acceptable response of this polymer shown by biocompatibility tests and by animal studies, in accordance to the following three tests and certifications:

1. ISO 10993 for Local Effects after Implantation, issued by the International Standards Organization (ISO),

2. FDA-Modified ISO-10993, Part 1 “Biological Evaluation of Medical Devices” tests issued by the U.S. Food and Drug Administration (FDA),

3. Class VI Biological Testing Procedures issued by the United States Pharmacopeial Convention, Inc. (USP).

The infiltration of nanotubes with PMMA was achieved by mixing the nanotubes with the monomer methyl methacrylate (MMA), followed by in situ polymerization. The specific recipe for the fabrication of aligned MWNT/PMMA films is described as follows. The monomer: methyl methacrylate (C₅H₈O₂, 99 wt %), initiator: 2, 2′-azobisisobutyronitrile (AIBN, C₈H₁₂N₄) and the chain transfer agent: 1-decanethiol (C₁₀H₂₂S, 96 wt %), were mixed together in a given proportion (60 ml MMA: 0.17 g AIBN: 30 μl-decanethiol), according to published techniques. A portion of this solution was then taken out in a glass vial, in which the substrate with aligned nanotube arrays was gently immersed—the nanotube-side facing the top. The remaining portion of the same solution was then taken in a separate vial to polymerize pure PMMA as a control sample. The resulting two quartz vials were then sealed in an Ar atmosphere and polymerization was carried out in a water bath at 55° C., for 24 hours. After polymerization, the glass vials were broken and the PMMA-MWNT and pure PMMA discs were extracted. The resulting films featured aligned MWNT in the PMMA polymer matrix.

The composite constructs were positioned in intimate contact with a multiple electrode array, as presented in FIG. 3. In this phase, the lower surface of the nanotube/PMMA composite was chemically and mechanically etched in order to expose the tips of the carbon nanotube bundles, therefore enabling electrical contact between underlying gold electrodes and vertically aligned carbon nanotubes.

The electrical resistance of these composites was measured at room temperature ex situ—separately from the IC—in a dry non-aqueous environment and was characterized to be equal to 1.8 kΩ. In particular, the measurement of the electrical resistance was performed by contacting one side of the composite with a copper plate and the opposite side of the composite with a 4 μm wide gold microtip. Since the relative dimensions of the recording tip used in the electrical measurement exceeded the diameter of individual nanotubes by two orders of magnitude, the electrical resistance measured corresponded to an aggregate measurement on bundles of adjacent carbon nanotubes and did not correspond to the resistance of individual multi-wall nanotubes.

The carbon nanotube/PMMA composites were characterized throughout each step of their synthesis by scanning electron microscopy. The arrays grown on silicon dioxide exhibited a high level of alignment and uniform length (FIG. 3). Most importantly, this alignment was preserved subsequent to the in situ polymerization process and the carbon nanotubes protruding from each side of the PMMA matrix exhibited electrical connectivity and conductivity between each side of the nanotube/PMMA composite.

Design and Fabrication of Gold-Plated Copper/Anodized Alumina Composite Interfaces Between Bio-Electrically Active Cells and ICs

Synthesis of Anodized Rational Alumina Templates. A 99.99% purity, high cubicity aluminum foil of about 100 μm thickness was inserted at the anode of an electrolytic potentiostatic cell. The term high cubicity refers to the rectangularly oriented aluminum grain structure which is intentionally produced in the foil. The electrolytic cell was comprised of a DC power supply, of a lead cathode (connected to the negative terminal of the power supply) and of the aluminum workpiece anode (connected to the negative terminal of the power supply). The electrolyte used was either a solution of oxalic acid in water (C₂H₂O₄, 0.3 M) or a solution of phosphoric acid in water (H₃PO₄, 0.3 M). Oxalic acid solutions were used in combination with a potential of 40 V, and generally lead to larger pore diameter than was the case with phosphoric acid solutions, which were used with a potential of about 20 V. Samples of anodized alumina templates were characterized by scanning electron microscopy, which shoed that the average pore size was smaller and more uniform when phosphoric acid was used as an electrolyte than in the case of alumina templates produced with oxalic acid as an electrolyte. A study of the cross-sections for both the substrates revealed a relative uniformity in the pore size across the cross-section, as well as continuous pore extension from side one side to the opposite one. The anodization process was a time-dependent phenomenon and on average the alumina templates were etched for about 8 hours, corresponding to a progression of the anodization equal to 60 μm through the thickness of the sample. The excessive aluminum was generally etched using a metal selective chemical etchant.

Conformal Copper Metallization of Anodized Rational Alumina Templates. The anodized alumina templates were coated on a single side with a seed layer of Cu (thickness: 50 μm) using e-beam evaporation. This layer was necessary in order to nucleate the copper crystal, therefore enabling the crystal growth process. Electron-beam evaporation is non-conformal and was not able to metallize the pores of the alumina template throughout their thickness, in light of the high aspect ratio of these structures. A conformal electrochemically-based metallization step was therefore pursued and is described in this section. The copper plated side of the template was then coated with a dielectric polymer. The resulting substrate was then contacted to the counter electrode of a potentiostatic setup. The working electrode of such setup was contacted to a copper bulk solid featuring a high surface area, which was used to dissolve the copper atoms and to transfer them inside the pores of the alumina template during the plating process. The reference electrode of the electrolytic cells was of the Hg—Hg—K₂SO₄ type, and the electrolyte was obtained by mixing 50 g of copper (II) sulfate pentahydrate (CuSO₄.5H₂O, 98 wt %) with 10 ml of sulphuric acid (H₂SO₄, 52-100 wt %) in 200 ml of DI water (H₂O). The copper plating of the template was time-dependent and was interrupted upon completion of the filling of the alumina pores. Although the completion of the pore fillup was clearly identifiable by a change in voltage on the potentiostat, excessive copper was usually deposited on the surface which had initially been coated with the Cu seed layer. In order to remove this layer of excessive copper, an electropolishing step was needed and is described in the following paragraph.

Conformal Electropolishing of the Excessive Copper on the Anodized Rational Alumina Templates. The alumina template featured pores which were completely filled throughout their length as well as cross-section. In addition, the surface which had been left unprotected by the dielectric film featured a layer of excessive copper deposited over the seed copper layer. This layer had to be removed in order to avoid cross-talk across the cross-section of the alumina template, therefore maintaining its lateral resolution and ensuring signal selectivity. The configuration of the working electrode and of the counter electrode was inverted from the one featured in the electro-plating electrolytic cell. The working electrode was now contacted with the copper-filled alumina template, while the counter electrode was set to contact the copper bulk solid with high surface area (Error! Reference source not found. below, right). The same Hg—Hg—K₂SO₄ reference electrode type was used and the electrolyte was obtained by mixing 103.64 ml of phosphoric acid (H₃PO₄, 85 wt %) with 146.59 ml of isopropyl alcohol ((CH₃)₂ CHOH, 99 wt %). The copper etch rate was carefully calibrated for the specific dimension of the template to electro-polish. The etch rate was increased by increasing the concentration of water or of phosphoric acid, while a decrease in etch rate was obtained by adding more isopropyl alcohol into the system. This molecule, in fact is less polar and contributes to reduce the dissociation of H₃PO₄.

Selective Alumina Etching. The alumina template was then mildly etched in a solution of phosphoric acid (H₃PO₄, 85 wt %) at 120° C. for a time interval which varied between 20 min and an hour. This step was used to change the profiles of the Cu rods from planar to three-dimensional.

Selective Electroless Gold Deposition on Copper. The copper tips protruding from the alumina template were selectively plated with gold in order to enhance long term viability of the device in the highly corrosive cellular medium, and to enhance biocompatibility. While copper oxide has a toxic effect on mammalian cells, gold is chemically inert and has not been demonstrated to significantly affect cellular metabolism. An immersion—gold, cyanide-free electroless chemical kit was used for this purpose.

As a final remark, the pores in the rational alumina templates were filled with copper high aspect ratio nanorods. The section of these rods which was protruding from the alumina template was selectively plated with gold using an immersion electroless process. This sequence was preferred to the direct deposition of gold inside the alumina pores in light of the lower costs of copper, coupled to the relative mild hazardous level of copper electrochemical processing. Gold electrochemical processing on the contrary evolves cyanide, therefore entailing a higher hazardous level.

The final appearance of the interface was characterized using field emission scanning electron microscopy and is reported in FIG. 4 Panel A, C, D. A thin platinum film was deposited on the composite construct shown in the micrographs of FIG. 4 in order to enhance contrast and reduce secondary electron charging during scanning electron microscopy characterization.

### EQUIVALENTS

While this invention has been particularly shown and described with references to example embodiments thereof, it will be understood by those skilled in the art that various changes in form and details may be made therein without departing from the scope of the invention encompassed by the appended claims.

1. A device, comprising:
a planar integrated circuit that includes an array of electrodes; and
at least one electrically conducting nanostructure in electrical contact with at least one electrode, said at least one nanostructure having a major axis.

2. The device of claim 1, wherein the at least one nanostructure includes a nanotube or a nanowire.

3. The device of claim 1, wherein the at least one nanostructure is made of a semiconductor.

4. The device of claim 1, wherein the at least one nanostructure is formed of carbon.

5. The device of claim 1 wherein the at least one nanostructure is an in situ formed metal nanostructure.

6. The device of claim 5, wherein the at least one nanostructure is formed of Cu, Au, Ag, Pt, or Ir.

7. The device of claim 1, wherein the major axis of the at least one nanostructure is non-coplanar with the plane of the integrated circuit.

8. The device of claim 1, further including electrical insulation disposed between two or more nanostructures.

9. The device of claim 8, wherein the electrical insulation is a polymer.

10. The device of claim 9, wherein the polymer is in situ formed polymethylmethacrylate (PMMA).

11. The device of claim 8, wherein the electrical insulation is an insulating layer, in which metal nanostructures are grown in situ.

12. The device of claim 1, wherein the nanostructures are chemically functionalized.

13. The device of claim 12, wherein the nanostructures are functionalized with inorganic ions, proteins, enzymes, nucleic acids, vitamins, antibodies, steroids and hormones, or aminoacids.

14. The device of claim 1, wherein the array of electrodes is an equidistant array.

15. The device of claim 1, wherein the integrated circuit has the minimum feature size of less than about 10 μm.

16. The device of claim 1, wherein the integrated circuit has the minimum feature size of less than about 1 μm.

17. The device of claim 1, wherein the integrated circuit has the minimum feature size of about 0.2 μm.

18. The device of claim 1, wherein the density of nanostructures per unit area is greater than about 1.2*10⁻³ channels per μm².

19. The device of claim 1, wherein the density of nanostructures per unit area is greater than about 0.12 channels per μm².

20. The device of claim 1, wherein the density of nanostructures per unit area is greater than about 1.68 channels per μm².

21. A method of manufacturing an electrical device, comprising:
growing two or more electrically conducting nanostructures in situ, said nanostructures having a major axis; and
electrically connecting the nanostructures with a planar integrated circuit that includes an array of electrodes, thereby forming an array of electrically conducting nanostructures.

22. The method of claim 21, wherein the major axis of the at least one nanostructure is non-coplanar with the plane of the integrated circuit.

23. The method of claim 21, further including a step of electrically insulating at least two electrically conducting nanostructures from one another.

24. The method of claim 23, wherein the electrical insulation is a polymer.

25. The method of claim 21, wherein the nanostructures include carbon nanotubes or bundles thereof in electrical contact with the array of electrodes.

26. The method of claim 25 wherein the step of electrically insulating at least two nanostructures from one another includes:
infiltrating the array of nanotubes or nanowires with a polymerizable monomer capable of forming electrical insulation; and
polymerizing the monomer in situ, thereby forming electrical insulation between at least two nanotubes or nanowires, or bundles thereof.

27. The method of claim 21, further including a step of growing the electrically conducting nanostructures within an insulating template.

28. The method of claim 21, further including the step of chemically functionalizing the nanostructures.

29. The method of claim 28, wherein the nanostructures are functionalized with inorganic ions, proteins, enzymes, nucleic acids, vitamins, antibodies, steroids and hormones, or aminoacids.

30. The method of claim 21, further including the step of fabricating the integrated circuit, wherein said step includes a combination of electron beam lithography and optical lithography.

31. The method of claim 21, wherein the array of electrodes is an equidistant array.

32. The method of claim 21, wherein the integrated circuit has the minimum feature size of less than about 10 μm.

33. The method of claim 21, wherein the integrated circuit has the minimum feature size of less than about 1 μm.

34. The method of claim 21, wherein the integrated circuit has the minimum feature size of about 0.2 μm.

35. The method of claim 21, wherein the density of nanostructures per unit area is greater than about 1.2*10⁻³ channels per μm².

36. The method of claim 21, wherein wherein the density of nanostructures per unit area is greater than about 0.12 channels per μm².

37. The method of claim 21, wherein the density of nanostructures per unit area is greater than about 1.68 channels per μm².

38. A method of recording or sending electrical signal to/from a biological cell, comprising contacting a biological cell with a device that includes:
a planar integrated circuit that includes an array of electrodes; and
at least one nanostructure having a major axis in electrical contact with at least one electrode.

39. The method of claim 38, wherein the biological cell is a myocardial cell, a neuronal cell, an osteoblast, a fibroblast, a skeletal muscle cell, a photoreceptor cell, or a cochlear hair cells.

40. The method of claim 38, wherein the biological cell is a progenitor stem cell selected from an embryonic stem cell, an adult stem cells, and an umbilical cord stem cells.

41. The method of claim 38, wherein the biological cell is in a pathological state caused by infectious diseases, cancer,s mental and behavioral disorders, inflammatory diseases, diseases of the eye, disorders of the ear, diseases of the circulatory system, congenital malformations, deformations and chromosomal abnormalities, or endocrine, nutritional and metabolic disorders.

42. The method of claim 38, wherein the at least one nanostructure includes a nanotube or a nanowire.

43. The method of claim 38, wherein the at least one nanostructure is made of a semiconductor.

44. The method of claim 38, wherein the at least one nanostructure is formed of carbon.

45. The method of claim 38, wherein the at least one nanostructure is an in situ formed metal nanostructure.

46. The method of claim 45, wherein the at least one nanostructure is formed of Cu, Au, Ag, Pt, or Ir.

47. The method of claim 38, wherein the major axis of the at least one nanostructure is non-coplanar with the plane of the integrated circuit.

48. The method of claim 38, wherein the device further includes electrical insulation disposed between two or more nanostructures.

49. The method of claim 48, wherein the electrical insulation is a polymer.

50. The method of claim 48, wherein the electrical insulation is an insulating layer, in which metal nanostructures are grown in situ.

51. The method of claim 38, wherein the nanostructures are chemically functionalized.

52. The method of claim 38, wherein the nanostructures are functionalized with inorganic ions, proteins, enzymes, nucleic acids, vitamins, antibodies, steroids and hormones, or aminoacids.

53. The method of claim 38, wherein the array of electrodes is an equidistant array.

54. The method of claim 38, wherein the integrated circuit has the minimum feature size of less than about 10 μm.

55. The method of claim 38, wherein the density of nanostructures per unit area is greater than about 1.2*10⁻³ channels per μm².

56. A method of diagnosing a disorder, comprising contacting a cell in a pathological state caused by said disorder with a device that includes:
a planar integrated circuit that includes an array of electrodes; and
at least one nanostructure having a major axis in electrical contact with at least one electrode,
wherein the disorder is cancer or a neurodegenerative disorder.
